(19) United States
(12) Patent Application Publication
(10) Pub. No.: US 2010/0148359 A1
(43) Pub. Date: Jun. 17, 2010

(54) Package on Package Assembly using Electrically Conductive Adhesive Material

(76) Inventors: Nanette Quevedo, Chandler, AZ (US); Myung Jin Yim, Chandler, AZ (US)

Correspondence Address: LEMOINE PATENT SERVICES, PLLC, PO BOX 307, LONG LAKE, MN, 55356-0307, US

(21) Appl. No.: 12/334,517

(22) Filed: Dec. 14, 2008

(51) Int. Cl. H01L 23/522; H01L 21/70

(52) U.S. Cl. 257/725; 257/723; 257/E23.142; 257/E21.532

(57) ABSTRACT

Packages are joined together using an anisotropic conductive material that includes an electrically insulative component and a plurality of electrically conductive particles. The electrically conductive particles may complete electrical connection between inter-package connectors and bond pads that may otherwise fail. The electrically insulative component may be cured to act as an underfill to provide mechanical connection between the packages.

### FIELD

The present invention relates generally to integrated circuits, and more specifically to packages for integrated circuits.

### BACKGROUND

Surface mount technology packages join a top package to a bottom package. Warpage can occur in either the top package or the bottom package resulting in connection failure between individual packages in the surface mount package assembly.

### BRIEF DESCRIPTION OF THE DRAWINGS

FIG. 1 shows a side view of an integrated circuit and a package;

FIG. 2 shows a side view of a package in a fabrication stage;

FIG. 3 shows a side view of a package in a fabrication stage;

FIG. 4 shows an alternate side view of a package in a fabrication stage;

FIG. 5 shows a side view of a package in a fabrication stage;

FIG. 6 shows a flow chart of a fabrication method; and

FIGS. 7 and 8 show diagrams of electronic systems in accordance with various embodiments of the present invention.

### DESCRIPTION OF EMBODIMENTS

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

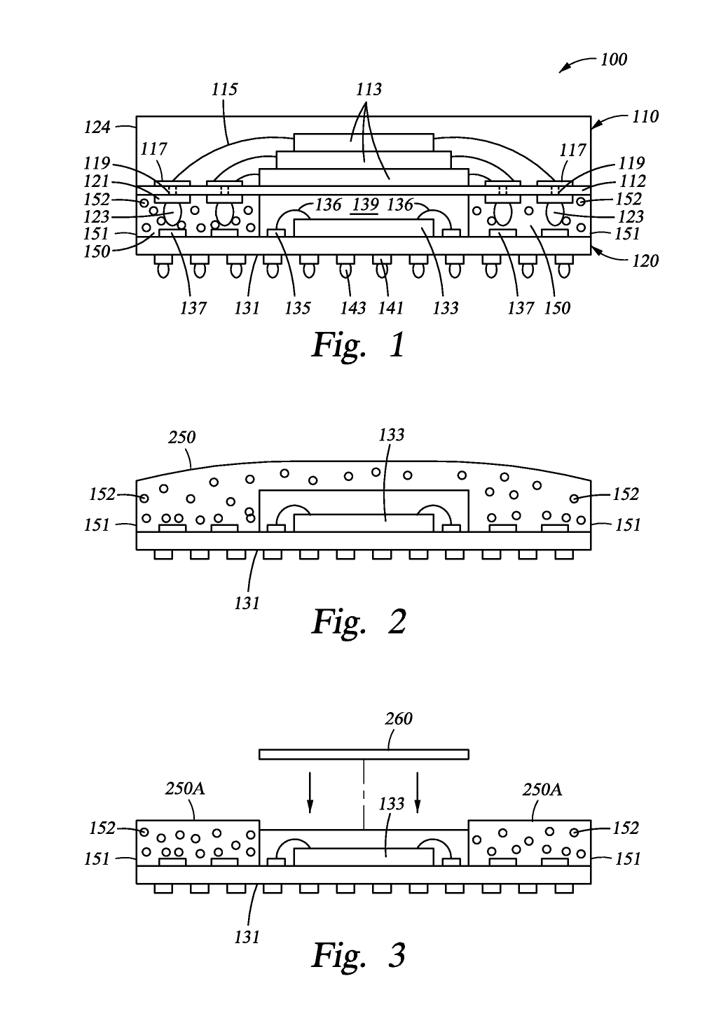

FIG. 1 shows a side view of a package on package assembly 100 including an integrated circuit first package 110 and an integrated circuit second package 120 electrically and mechanically joined together to provide additional electronic functionality in a single assembly of a multi-chip module than either package 110 or 120 can provide on its own. In some embodiments, the first package 110 may include memory devices or dice, such as random access memory, nonvolatile memory, flash memory, NOR-type memory, dynamic memory, or other memory types. The second package 120 may include logic circuits to control the first package and/or additional memory devices.

The first package 110 includes a substrate 112 on which are mounted a plurality of stacked dice 113 or at least one die 113. The substrate 112 may be a printed circuit board or substrate to support the dice 113. The substrate 112 may be a board in a Chip-On-Board configuration. The substrate 112 may be any type of substrate or interposer, which is compatible with dice 113. Any type of substrate, such as a circuit board, a semiconductor device, and the like are within the scope of the present invention. The substrate 112 may be formed from silicon, glass, ceramic, an organic material, metal, semiconductor material, or the like. The die 113 may include a semiconductor device that includes, for example, a semiconductor device of silicon, gallium arsenide, indium phosphide or other semi-conductive material configured as a processor, logic, memory or other electrical function, wherein integrated circuitry is fabricated on an active surface of the device while part of a wafer or other bulk semiconductor substrate that is later “singulated” to form a plurality of individual semiconductor dice. The bottom most die is fixed to the substrate 112 by any suitable die attach material, for example, thermoset resin, pressure sensitive adhesive, an adhesive-coated film or tape, and the like. Adjacent dice 113 are likewise fixed together and may be in electrical communication by through vias. While the dice 113 are shown being of different dimensions, it is within the scope of the present invention to join dice of the same size and function.

A plurality of wires 115 connect bond pads (not shown) on the dice 113 with bond pads 117 on the substrate 112. The bond pads 117 are positioned around the perimeter of the dice stack. A plurality of through substrate electrical connections 119 connect the die-side bond pads 117 to bond pads 121 that are positioned on the opposite side of the substrate 112 from the dice 113. A plurality of package interconnects 123 are mounted to the bond pads 121. In some embodiments, the package interconnects 123 are balls that may provide electrical communication between the first and second packages 110, 120. In some embodiments, the package interconnects 123 are solder balls. In some embodiments, the package interconnects 123 are metal bumps and may include noble metals such as gold.

An encapsulant 124 covers the top surface of the substrate 112 and die or dice 113 and encloses the bond pads 117, wires 115, and the sides and top of the dice 113. The encapsulant 124 protects the remainder of the top side of the first package 110 from dust, debris, moisture, and other harmful material.

The second package 120 includes a substrate 131 on which are mounted at least one die 133. The substrate 131 may be a printed circuit board or substrate to support the die 133. The substrate 132 may be a board in a Chip-On-Board configuration. The substrate 131 may be any type of substrate or interposer, which is compatible with die 133. Any type of substrate, such as a circuit board, a semiconductor device, and the like are within the scope of the present invention. The substrate 131 may be formed from silicon, glass, ceramic, an organic material, metal, semiconductor material, or the like. The die 133 may include a semiconductor device that includes, for example, a semiconductor device of silicon, gallium arsenide, indium phosphide or other semi-conductive material configured as a processor, logic, memory or other electrical function, wherein integrated circuitry is fabricated on an active surface of the device while part of a wafer or other bulk semiconductor substrate that is later “singulated” to form a plurality of individual semiconductor dice. In some embodiments, the die 133 includes logic circuits, controller circuits, processor circuits, or combinations thereof. In one example, the die 133 includes control circuits to control the memory functions of the first package 110. The die 133 is fixed to the substrate 131 by any suitable die attach material, for example, thermoset resin, pressure sensitive adhesive, an adhesive-coated film or tape, and the like.

A plurality of bond pads 135 are positioned around the periphery of the die 133. A plurality of wires 136 electrically connect the circuits in the die 133 to die bond pads 135. A plurality of traces in or on the substrate electrically connect bond pads 135 to interpackage bond pads 137. Interpackage bond pads 137 are to electrically and mechanically connect to the interconnects 123 of the first package. An encapsulant 139 encloses the die 133, the wires 136, and the die bond pads 135. The encapsulant 139 protects these elements and stiffens the package. When connected, the encapsulated die 133 is in contact with the bottom side of the first package substrate 112.

A plurality of input/output bond pads 141 are positioned on a side of the substrate remote from the die 133. The input/output bond pads 141 are electrically connected to bond pads 121 through interconnects 121 or to bond pads 135. Interconnects 143, such as solder balls or bumps, are positioned on the bond pads 141. The bond pads 141 and interconnects 143 connect the package to package assembly 100, including dice 113 and die 133 to external circuits.

A connection material 150 is positioned intermediate the first package 110 and the second package 120 outside the encapsulated die 133 of the second (bottom as shown in FIG. 1) package 120. The connection material 150 includes a first component 151 that may be an electrically insulator compliant material 151 and a second component 152 that is electrically conductive and embedded in the electrical insulator component 151. The connection material 150 may be an anisotropic conductive paste or an anisotropic conductive film. In some embodiments, the connection material 150 may be an anisotropic conductive adhesive. The connection material 150 provides a mechanical connection between the first package 110 and the second package 120. The connection material 150 further provides an electrical connection between the interconnect 123 and the bond pad 137. More particularly, the second component 152 provides electrical communication when the interconnect 123 is not in contact with the bond pad 137.

In some embodiments, second component 152 may be metal particles or metal-coated polymer particles. Examples of metal coatings include gold, copper, silver, aluminum, and nickel. The particles are smaller than the interconnects 123. In some embodiments, the particles have a dimension, e.g., a diameter, of about 3 micrometers to about 10 micrometers, although this is not a limitation of the present invention. The second components 152 are sufficient in number to provide electrical communication but not so numerous as to short adjacent interconnects 123 together or adjacent bond pods 137 together. As a result of this structure, warpage of either of the first package 110 or the second package 120, which otherwise might result in failure of the joint between the interconnect 123 and bond pad 137, can be compensated for to ensure electrical communication between the first package and the second package.

FIG. 2 shows a schematic, side view of a second package 220 during a fabrication stage. Here the die 133 is fixed to the substrate 131 with the appropriate wires and encapsulation. In some embodiments, the anisotropic conductive film 250 may be dispensed from a source reel (not shown). The film 250 may have a width matching the package 220. The film 250 is cut to length and now covers the second package including the encapsulated die 233. The film 250 over the encapsulated die is removed so as to not increase the effective height of the second package.

FIG. 3 shows a punch 260 that, in some embodiments, has substantially the same dimension as the encapsulated die 233. The punch 260 contacts the film 250 that is over the encapsulated die 233 and removes this portion of the film 250. The remaining film portion 250A is around the periphery of the encapsulated die. In some embodiment, the film portion 250A includes a backing on its rear surface to prevent it from adhering to itself or an applicator of the anisotropic conductive film.

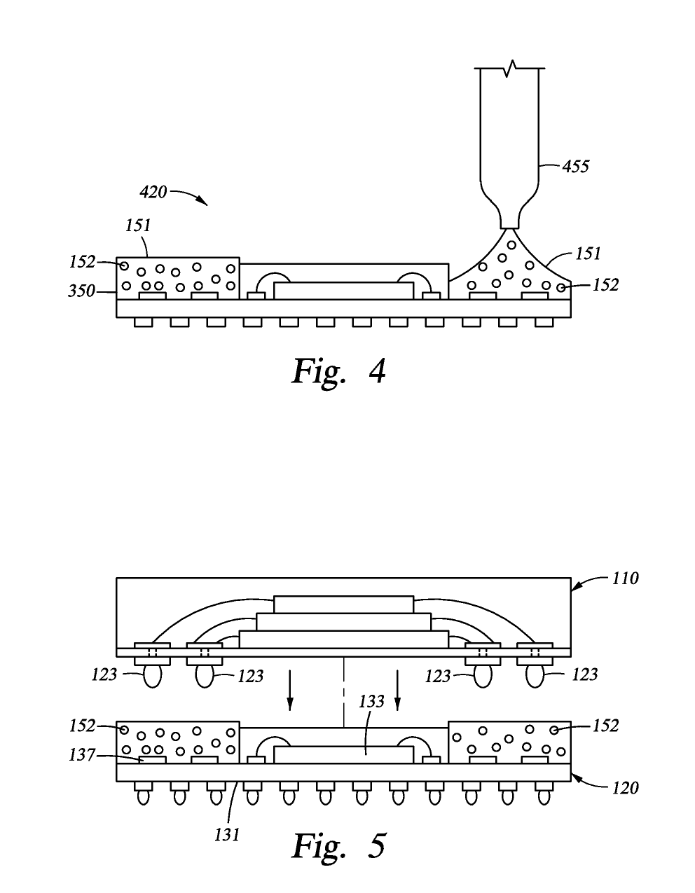

FIG. 4 shows an alternate schematic, side view of a second package 420 during a fabrication stage. Here the die 233 is fixed to the substrate 231 with the appropriate wires and encapsulation. An anisotropic conductive paste 450 is dispensed from a nozzle 455 around the periphery of the encapsulated die 133.

As shown in FIGS. 2-4 the conductive material, here anisotropic conductive film 250 and anisotropic conductive paste 450 extend above the encapsulated die 133. This allows the conductive material to be compressed during connection to the other package.

FIG. 5 shows the assembly of the top, first package 110 to the bottom, second package 120, 220, or 420. The top package 110 is aligned with the bottom package and pressed downward so that the interconnects 123 penetrates through the connection material 150, 250, or 450. At least one of the interconnects 123 traps one or more conductive particles 152 between the interconnect and the respective bond pad 137. If an interconnect does not have an adequate connection to be electrically conductive with the bond pad directly, the conductive particle(s) in contact with both the interconnect and the bond pad completes an electrically conductive contact.

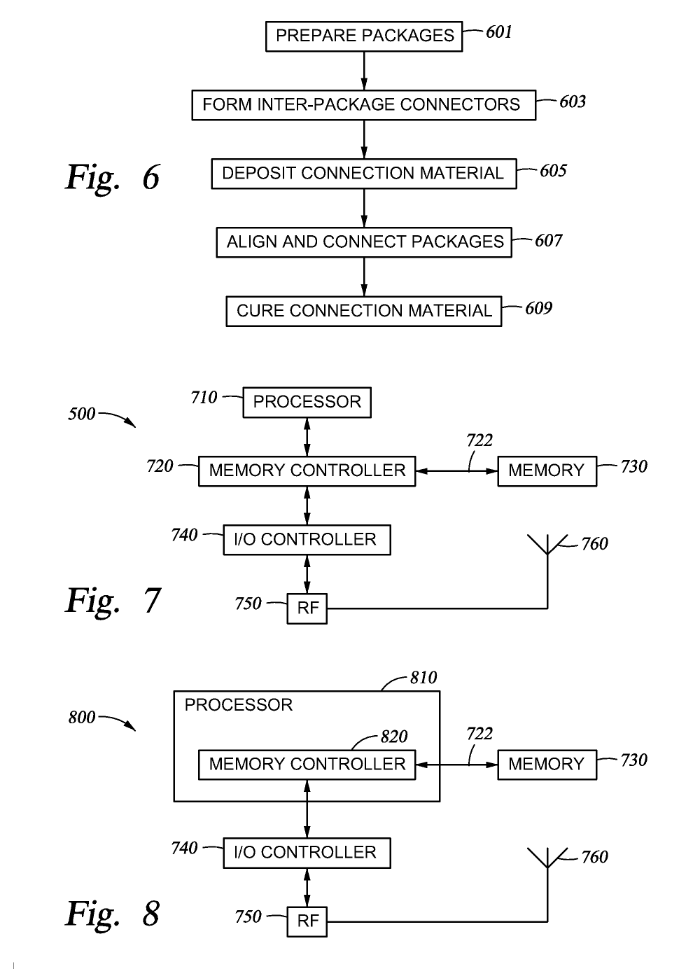

FIG. 6 shows a flow chart of a fabrication method. In 601, the first and second packages are formed. Traces and conductive vias are patterned on the substrate to provide electrical communication paths. Bond pads are formed in electrical communication with the traces and vias. Dice are fixed to the substrates and electrically connected to bond pads, for example, by wire bonds. The dice and other components are encapsulated to protect the dice and other parts from environmental contaminants and physical contact that can cause electrical or mechanical failure. In 603, inter-package connectors, such solder balls, metal bumps, etc., are formed on select bond pads.

In 605, the connection material is deposited around encapsulated die or dice. In some embodiments, the connection material is an anisotropic conductive material that includes an insulative, compliant component and electrically conductive particles. The anisotropic conductive material may be in the form of a film that is rolled over a package or a paste that is dispensed onto the bond pads. In some embodiments, the anisotropic conductive material does not cover the encapsulated die but is positioned over the bond pads. This does not increase the height of the package assembly. In some embodiments, the anisotropic conductive material is flowable or compliant to allow it to be patterned on the package and allow its penetration by connectors.

In 607, two packages are aligned with some inter-package connections on one package aligned with bond pads of another package. The bond pads are covered by the connection material. The inter-package connections penetrate the connection material and may trap conductive particles of the connection material on the respective bond pads. Thus, if an inter-package connection does not create a reliable joint, e.g., mechanical and electrical connection, the particles will ensure electrical connection. The connection material can assist in eliminating open joints between two packages. Such open joints can be the result of package warpage (deflection from a planar orientation) on a small scale, e.g., less than 10 micrometers. Accordingly, device failure caused by package warpage is reduced. Embodiments of the present invention may further correct for the malformation of the height of the lower package relative to the pitch of the inter-package connection, e.g., solder ball or bump, that may result in the inter-package connection not forming a suitable electrical or mechanical joint between the packages.

In 609, the connection material is cured. The connection material may be selected such that the connection material is a fast, low temperature curing resin, polymer, or epoxy. This will result in the curing of the connection material not requiring much of the thermal budget of either package or dice. In some embodiments, the anisotropic conductive component of the connection material is cured at about 200° C. for about 5 to 60 seconds. The two packages may be pressed together such that the connection material is under pressure. The pressure may be about 10-400 grams/bump. In a specific example, the anisotropic conductive component is cured at about 150-210° C., under pressure of 40-300 grams/bump for about 5-20 seconds. Once cured, the connection material may act as an underfill to secure the two packages together.

FIG. 7 shows an electronic system in accordance with various embodiments of the present invention. Electronic system 700 includes processor 710, memory controller 720, memory 730, input/output (I/O) controller 740, radio frequency (RF) circuits 750, and antenna 760. In operation, system 700 sends and receives signals using antenna 760, and these signals are processed by the various elements shown in FIG. 7. Antenna 760 may be a directional antenna or an omni-directional antenna. As used herein, the term omni-directional antenna refers to any antenna having a substantially uniform pattern in at least one plane. For example, in some embodiments, antenna 760 may be an omni-directional antenna such as a dipole antenna, or a quarter wave antenna. Also for example, in some embodiments, antenna 760 may be a directional antenna such as a parabolic dish antenna, a patch antenna, or a Yagi antenna. In some embodiments, antenna 760 may include multiple physical antennas.

Radio frequency circuit 750 communicates with antenna 760 and I/O controller 740. In some embodiments, RF circuit 750 includes a physical interface (PHY) corresponding to a communications protocol. For example, RF circuit 750 can include modulators, demodulators, mixers, frequency synthesizers, low noise amplifiers, power amplifiers, and the like. In some embodiments, RF circuit 750 can include a heterodyne receiver, and in other embodiments, RF circuit 750 can include a direct conversion receiver. In some embodiments, RF circuit 750 can include multiple receivers. For example, in embodiments with multiple antennas 760, each antenna can be coupled to a corresponding receiver. In operation, RF circuit 750 receives communications signals from antenna 760, and provides analog or digital signals to I/O controller 740. Further, I/O controller 740 can provide signals to RF circuit 750, which operates on the signals and then transmits them to antenna 760.

Processor 710 may be any type of processing device. For example, processor 710 can be a microprocessor, a microcontroller, or the like. Further, processor 710 can include any number of processing cores, or can include any number of separate processors.

Memory controller 720 provides a communications path between processor 710 and other devices shown in FIG. 7. In some embodiments, memory controller 720 is part of a hub device that provides other functions as well. As shown in FIG. 7, memory controller 720 is coupled to processor 710, I/O controller 740, and memory 730.

Memory 730 may be any type of memory technology. For example, memory 730 may be random access memory (RAM), dynamic random access memory (DRAM), static random access memory (SRAM), nonvolatile memory such as FLASH memory, or any other type of memory. In some embodiments, the memory controller 720 may be on one package and the memory may be in multiple dice stacked in another package.

Memory 730 may represent a single memory device or a number of memory devices on one or more memory modules. Memory controller 720 provides data through bus 722 to memory 730 and receives data from memory 730 in response to read requests. Commands and/or addresses may be provided to memory 730 through conductors other than bus 722 or through bus 722. Memory controller 730 may receive data to be stored in memory 730 from processor 710 or from another source. Memory controller 720 may provide the data it receives from memory 730 to processor 710 or to another destination. Bus 722 may be a bi-directional bus or unidirectional bus. Bus 722 may include many parallel conductors. The signals may be differential or single ended.

Memory controller 720 is also coupled to I/O controller 740, and provides a communications path between processor 710 and I/O controller 740. I/O controller 740 includes circuitry for communicating with I/O circuits such as serial ports, parallel ports, universal serial bus (USB) ports, and the like. As shown in FIG. 7, I/O controller 740 provides a communications path to RF circuits 750.

In various embodiments of the present invention, one or more of the integrated circuits in system 700 are packaged then joined to another package through the connection material as described herein. For example, memory controller 720 may be a packaged integrated circuit that has rectangular, polar, and irregular patterned solder balls. Any of the embodiments described herein may be utilized with any of the circuits of system 700.

FIG. 8 shows an electronic system in accordance with various embodiments of the present invention. Electronic system 800 includes memory 730, I/O controller 740, RF circuits 750, and antenna 760, all of which are described above with reference to FIG. 7. Electronic system 800 also includes processor 810 and memory controller 820. As shown in FIG. 8, memory controller 820 is included in processor 810. Processor 810 may be any type of processor as described above with reference to processor 710 (FIG. 7). Processor 810 differs from processor 710 in that processor 810 includes memory controller 820, whereas processor 710 does not include a memory controller.

Example systems represented by FIGS. 7 and 8 include desktop computers, laptop computers, cellular phones, personal digital assistants, wireless local area network interfaces, or any other suitable system. Many other systems uses for integrated circuits packaged in package-to-package assemblies exist. For example, the various embodiments described herein may be used in a server computer, a network bridge or router, or any other system with or without an antenna.

Further, systems represented by FIGS. 7 and 8 may be systems capable of performing the design of a package assemblies as described herein. For example, instructions for the various method embodiments of the present invention may be stored in memory 730, and processor 710 or processor 810 may perform the operations associated with the methods.

While the embodiments described herein are directed to two packages joined through a connection material that includes an insulative, compliant component and a plurality of conductive particles, it is within the scope of embodiments of the present invention to stack any number of packages utilizing the connection material and methods as described herein.

Although the present invention has been described in conjunction with certain embodiments, it is to be understood that modifications and variations may be resorted to without departing from the scope of the invention as those skilled in the art readily understand. Such modifications and variations are considered to be within the scope of the invention and the appended claims.

What is claimed is:

1. An integrated circuit assembly comprising:
a first integrated circuit package;
a second integrated circuit package;
a plurality of inter-package connectors to electrically connect the first package to the second package; and
a connection material comprising a compliant electrical insulator component and a plurality of electrically conductive components embedded in the electrical insulator component, wherein the plurality of electrically conductive components ensure electrical connection of the first package to the second package.

2. The integrated circuit assembly of claim 1, wherein the compliant electrical insulator component comprises a polymer.

3. The integrated circuit assembly of claim 2, wherein the plurality of electrically conductive components comprise at least one of metallic particles and metal-coated polymer particles.

4. The integrated circuit assembly of claim 1, wherein the plurality of inter-package connectors includes balls to connect to pads on the second integrated circuit package, and wherein the plurality of electrically conductive components electrically connect at least one ball to a respective pad.

5. The integrated circuit assembly of claim 4, wherein the balls include solder balls.

6. The integrated circuit assembly of claim 4, wherein the first integrated circuit package is warped such that the balls do not make a reliable electrical connection to the pads on the second integrated circuit package, and wherein some of the plurality of electrically conductive components complete an electrical connection between at a ball displaced from the respective bond pad due to the displacement of the first integrated circuit package due to warpage.

7. The integrated circuit assembly of claim 4, wherein the first integrated circuit package comprises a first substrate and at least one memory die mounted to the first substrate, the first substrate including a plurality of die-side pads in electrical communication with the at least one memory die and a plurality of opposite-side pads in electrical communication with the plurality of die-side pads, wherein the balls are fixed on the opposite-side pads.

8. The integrated circuit assembly of claim 7, the second integrated circuit package comprises a second substrate and at least one logic circuit mounted to the second substrate, the second substrate including a plurality of package interconnect pads in electrical communication with the at least one logic circuit and a plurality of input/output pads in electrical communication with the at least one logic circuit, and wherein the connection material is on the package interconnect pads that will receive the balls.

9. The integrated circuit assembly of claim 1, wherein the connection material comprises an anisotropic conductive adhesive.

10. A method comprising:
applying a connection material, which comprises a compliant electrical insulator component and a plurality of electrically conductive components embedded in the electrical insulator component, to a first package outside of a die;
positioning a second package in alignment with the first package; and
curing the connection material to provide an electrical connection between the first package and the second package through the connection material.

11. The method of claim 10, wherein curing the connection material comprises heating the compliant insulator material.

12. The method of claim 11, wherein curing the connection material comprises pressing the first and second packaged together to compress the connection material.

13. The method of claim 10, wherein positioning comprises aligning inter-package connectors with bond pads and pressing the inter-package connectors through the connection material.

14. The method of claim 13, wherein curing the connection material comprises heating the connection material to 150-210° C. under pressure of 40-300 grams per bond pad for about 5-20 seconds.

15. The method of claim 10, wherein applying connection material includes rolling an anisotropic conductive film over the first package, wherein the first package includes an encapsulated die.

16. The method of claim 15, wherein applying the connection material includes punching out a portion of the anisotropic conductive film from over the encapsulated die.

17. The method of claim 10, wherein applying the connection material includes dispensing an anisotropic conductive paste over bond pads and not on the die.

18. A system comprising:
an antenna;
radio frequency circuit coupled to the antenna; and
an integrated circuit coupled to the radio frequency circuit, the integrated circuit comprising:
a memory package;
a logic package;
a plurality of inter-package connectors to electrically connect the memory package to the logic package; and
a connection material comprising a compliant electrical insulator component and a plurality of electrically conductive components embedded in the electrical insulator component, wherein the plurality of electrically conductive components ensure electrical connection of the memory package to the logic package.

19. The system of claim 18, wherein the plurality of electrically conductive components comprise at least one of metallic particles and metal-coated polymer particles.

20. The system of claim 18, wherein the connection material comprises an anisotropic conductive adhesive.
